(19) United States
(12) Patent Application Publication
(10) Pub. No.: US 2014/0173374 A1
(43) Pub. Date: Jun. 19, 2014

(54) METHODS AND APPARATUS FOR ERROR CODING

(71) Applicant: Broadcom Corporation, Irvine, CA (US)

(72) Inventor: Esko Juhani NIEMINEN, Oulu (FI)

(73) Assignee: Broadcom Corporation, Irvine, CA (US)

(21) Appl. No.: 14/108,759

(22) Filed: Dec. 17, 2013

(30) Foreign Application Priority Data
Dec. 19, 2012 (GB) 1222909.2

(51) Int. Cl. H03M 13/11; H03M 13/27

(52) U.S. Cl. CPC H03M 13/1105; H03M 13/276
USPC 714/752

(57) ABSTRACT

Methods and apparatus are described for implementing low-density parity-check codes. These may be used in electronic communications, such as wireless communication systems. A number of processes are implemented for each vector in a plurality of vectors of a coding matrix associated with a low-density parity-check code. These include retrieving, from one or more interleavers, one or more addresses, using the or each retrieved address to retrieve one or more symbols from data and determining a parity-check operation corresponding to a particular said vector using said one or more symbols retrieved from said data. This enables an encoded block to be generated using said data and each of the parity-check operations. It also enables a received code vector to be decoded.

### TECHNICAL FIELD

The present invention relates to methods and apparatus for implementing error coding. In particular, the present invention is directed towards an implementation of a low-density parity-check code scheme, for example for use in electronic communications.

### BACKGROUND

In the field of electronic communications, data often needs to be transmitted over unreliable or noisy communication channels. To minimise or avoid errors forward error correction or channel coding is often used. These schemes use a code to ensure reliable communication. In binary transmissions, a code comprises a finite set of symbol sequences (alternatively referred to as code-vectors or code-words) that are correlated to enable error detection and correction. These symbol sequences are typically of a fixed size referred to as a block length. In modern wireless communications systems, for example, forward error correction or channel coding is used to avoid errors in data transmitted to and from mobile computing devices, including cellular devices. Any decoding error is dependent on at least the block length.

Many advanced telecommunications systems make use of turbo codes to perform forward error correction. These provide a form of probabilistic processing that uses a likelihood measure to iteratively decode an encoded stream. For example, they are used in 3G and 4G (third and fourth generation) standards such as High Speed Packet Access (HSPA) and Long-Term Evolution (LTE).

Recently, low-density parity-check codes, a class of linear block codes, have also found use in digital applications. Although first developed in 1963 by Robert Gallager, these codes were ignored for many years. They were only rediscovered and developed practically in the late 1990s. Low-density parity-check codes are now used in, amongst others: wireless and wired networking standards, digital video broadcasting standards, and microwave communication standards. Linear block codes have an advantage in that a bit sequence may be generated as a linear combination of input bit sequences comprising the information to be transmitted.

Low-density parity-check codes make use of a parity-check matrix, H, to determine a particular low-density parity-check code for one or more symbols, typically information bits. The parity-check matrix is sparse, i.e. has M zero values and N non-zero values where M>>N. In general, the rows and columns of a sparse matrix will primarily contain zeros, e.g. the number of zero entries in each row and/or column will be above a particular threshold associated with the size of the matrix. The term “low-density” for low-density parity-check codes refers to this characteristic of the parity-check matrix, i.e. the density of non-zero values is low. Reference may be made to the weight w of a column (w_{c}) or a row (wᵣ), which is the number of entries with a bit value of 1. For a sparse matrix of size m×n to be used for determining low-density parity-check codes, wᵣ<<m and wₑ<<n. A low-density parity-check code is called regular if wᵣ·m=w_{c}·n; otherwise a code is irregular.

A low-density parity-check matrix may be represented using a sparse bipartite graph, in particular a Tanner graph. A Tanner graph for an example of a low-density parity-check code is shown in FIG. 1. This example 100 has the following low-density parity-check matrix:

$$H = [ \begin{matrix}0 & 1 & 0 & 1 & 1 & 0 & 0 & 1 \\ 1 & 1 & 1 & 0 & 0 & 1 & 0 & 0 \\ 0 & 0 & 1 & 0 & 0 & 1 & 1 & 1\end{matrix} ]$$

This is a relatively simple matrix set out to describe the operation of low-density parity-check codes. In this case, a code or vectors is eight bits in length, i.e. comprises eight 1-bit terms. The matrix H determines code vectors c=(c₁, c₂, . . . , c₈) by the linear equation:

c·H^{T}=0,

where H^{T} is a transpose of matrix H. Every code vector satisfies three parity check equations. The matrix H has three linearly independent rows. A code rate of the code of the matrix H is (8−3)/8=5/8. In a real-world implementation, the matrix may be much larger, for example 3000×6000 to encode a data block of 3000 bits at a 1/2 code rate, and much sparser, for example having w_{c} and wᵣ in the order of 10⁰ or 10¹.

As can be seen in FIG. 1, the parity-check matrix, H, provides parameters for two types of nodes in the Tanner graph: variable nodes 110 and check nodes (or functional nodes) 120. Check node fᵢ is connected to variable node if the element hᵢⱼ of H has a bit value of 1 (where i is a row index in H and j is a column index in H, for i=1 to m and j=1 to n for an m×n matrix). The columns of the low-density parity-check matrix thus represent the connections of each variable node 110 and the rows represent the connections of each check node 120. The set of bit sequences for a particular low-density parity-check code are constructed according to the low-density parity-check matrix.

FIGS. 2A and 2B demonstrate how a low-density parity-check code is decoded. The code is decoded using a belief-propagation or message-passing algorithm (the two terms are often used interchangeably) that is constructed based on the bipartite graph representation. For example, as shown in FIG. 2B, messages qᵢⱼ(b) representing a particular received bit vᵢ are passed from the variable nodes cᵢ 110 to the check nodes fⱼ 120. Each check node in the algorithm applies one or more parity checks based on one or more sets of bit values received in the messages from the variable nodes connected to the check node and returns the result rⱼᵢ(b) of these calculations to each of the connected variable nodes. The result may be a hard or soft decision variable. If all parity check equations are satisfied then the algorithm ends as the bit sequence was received successfully. If certain ones of the parity check equations are not satisfied then each variable node updates its message qᵢⱼ(b) for the check nodes based on a received result rⱼᵢ(b) and the method is iterated until the parity check equations are satisfied or one or more stop criteria are reached.

Some examples of applications of low-density parity-check codes will now be briefly described.

US 2012/0189079 A1 describes a data processing apparatus that comprises a parity interleaver operable to perform parity interleaving on low-density parity-check encoded data bits. These data bits are obtained by performing low-density parity-check encoding according to a parity check matrix of a low-density parity-check code. In this document a parity matrix portion of the parity check matrix corresponding to parity bits of the code has a stepwise structure. Parity bits are generated based on the low-density parity-check matrix. Following this the parity bits are interleaved to a different parity bit position. A mapping unit maps the parity interleaved bits onto data symbols corresponding to modulation symbols of a modulation scheme of orthogonal frequency division multiplexed sub-carrier signals.

US 2008/0082894 A1 describes an approach for generating low-density parity-check codes. An encoder generates a short low-density parity-check code by shortening longer mother codes. The short code has an outer Bose Chaudhuri Hocquenghem (BCH) code. According to another aspect, for a particular low-density parity-check code with code rate of 3/5 utilizing 8-PSK (Phase Shift Keying) modulation, an interleaver provides for interleaving bits of the output LDPC code by serially writing data associated with the LDPC code column-wise into a table and reading the data row-wise from right to left. This approach has particular application in digital video broadcast services over satellite.

In many applications of low-density parity-check codes there is a large block length and thus a large low-density parity-check matrix size. For example, a 3000×6000 matrix is required to encode a data block of 3000 bits at a 1/2 code rate, which requires 18,000,000 matrix elements. In general, a code rate is derived from dimensions of an m×n parity check matrix by k/n where k=n−m (i.e. a code rate=(n−m)/n), where a number of linearly independent rows in H is equal to a number of data bits to be encoded. As the matrix is sparse the majority of these elements will have a binary value of 0.

In certain cases, to avoid these problems a low-density parity-check matrix is defined in terms of one or more small sub-matrices. For example, US 2012/0189079 A1 uses a parity matrix with a step-like structure and US 2008/0082894 A1 constrains certain portions of a parity-check matrix to be triangular. These kinds of techniques can result in sub-optimal low-density parity-check codes.

It would be advantageous to improve the implementation of low-density parity-check codes.

### SUMMARY

In accordance with a first example, there is provided a method of implementing a low-density parity-check code comprising receiving data; for a plurality of vectors in a coding matrix associated with the low-density parity-check code: retrieving, from one or more interleavers, one or more addresses; using said one or more retrieved address to retrieve one or more symbols from said data; and performing a parity-check operation corresponding to a particular said vector using said one or more symbols retrieved from said data, wherein each of the performed parity-check operations are used to implement the low-density parity-check code.

In accordance with a second example, there is provided apparatus for implementing a low-density parity-check code comprising: at least one memory arranged to store data; one or more interleavers, an interleaver being arranged to implement a mapping between a first address and a second address, a first address being associated with a particular vector in a coding matrix associated with the low-density parity-check code and a second address corresponding to a particular symbol of the data as stored in the memory; a coding component arranged to, for a plurality of vectors in the coding matrix, use one or more second addresses from the one or more interleavers to retrieve one or more symbols of the data stored in memory, the coding component being further arranged to perform at least a plurality of parity check operations, a parity check operation corresponding to a vector in the coding matrix and being performed using said retrieved one or more symbols of the data, the plurality of parity check bits being used to implement the low-density parity-check code.

In accordance with a third example, there is provided apparatus comprising: at least one processor; and at least one memory including computer program instructions and data; the at least one memory and the computer program instructions being configured to, with the at least one processor, cause the apparatus at least to, for a plurality of vectors in a coding matrix associated with a low-density parity-check code: retrieve, from one or more interleavers, one or more addresses; use said one or more retrieved address to retrieve one or more symbols from said data in memory; and perform a parity-check operation corresponding to a particular said vector using said one or more symbols retrieved from said data, wherein each of the performed parity-check operations are used to implement the low-density parity-check code.

In accordance with a fourth example, there is provided a method of configuring one or more interleavers for use in implementing a low-density parity-check code comprising: selecting a coding matrix associated with the low-density parity-check code; and determining one or more interleaver parameters that implement a mapping for one or more interleavers from a first address corresponding to a vector in the coding matrix to a second address corresponding to a symbol position in data to be encoded or decoded, the mapping being selected from a plurality of potential mappings based on one or more error coding criteria.

Further features and advantages of the invention will become apparent from the following description of some embodiments of the invention, given by way of example only, which is made with reference to the accompanying drawings.

### BRIEF DESCRIPTION OF THE DRAWINGS

FIG. 1 is a schematic diagram showing a Tanner graph for an example of a low-density parity-check matrix;

FIGS. 2A and 2B are schematic diagrams of a portion of the Tanner graph of FIG. 1 that demonstrate message and result passing in an example decoding algorithm for low-density parity-check codes;

FIG. 3 is a schematic diagram of a communications channel according to an example;

FIGS. 4A and 4B are schematic diagrams respectively showing examples of a transmitter and a receiver for use with the communications channel of FIG. 3;

FIG. 5A is representation of a low-density parity-check matrix according to an example;

FIG. 5B is representation of the low-density parity-check matrix of FIG. 5A following Gaussian elimination;

FIG. 6 is a representation of a generator matrix based on the representation of FIG. 5B;

FIG. 7 is a schematic diagram of apparatus for implementing a low-density parity-check code according to an example;

FIG. 8 is a schematic diagram of apparatus for implementing a low-density parity-check code according to another example;

FIG. 9A is a flow diagram showing a method of implementing a low-density parity-check code according to an example; and

FIG. 9B is a flow diagram showing a method of implementing a low-density parity-check code according to another example.

### DETAILED DESCRIPTION

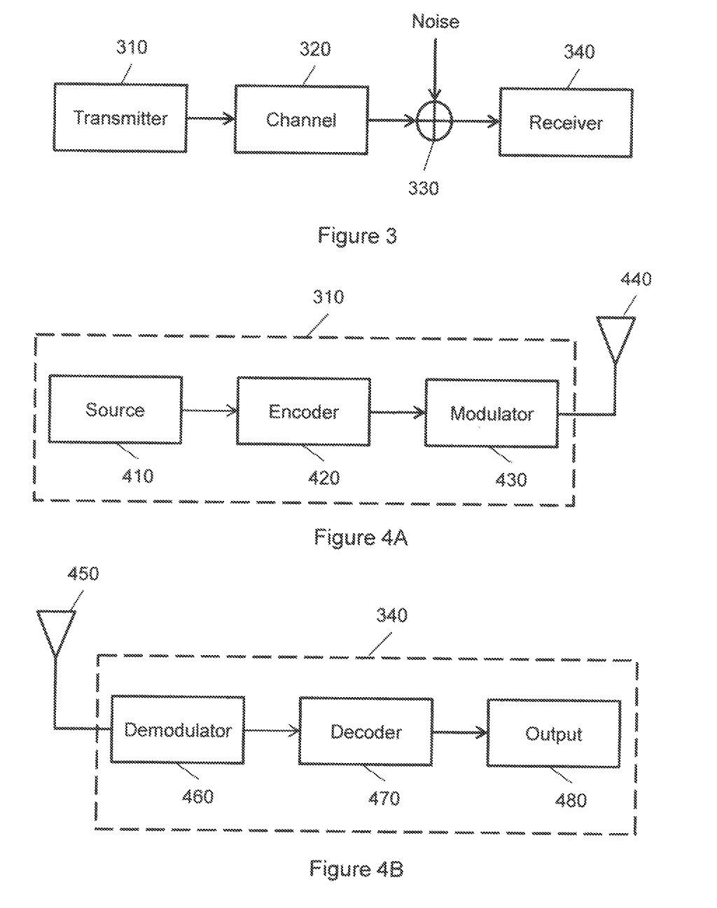

FIG. 3 shows a model of a communications system that may use the low-density parity-check coding implementations described herein. A transmitter 310 transmits data over a communications channel 320 to a receiver 340. The transmission of data in this example is affected by additive noise 330 that has the potential to introduce errors into the transmitted data. Other noise models are also possible. As described previously, to avoid these errors, and in certain cases correct errors without retransmission, forward error correction may be used.

FIG. 4A shows an example of the transmitter 310 of FIG. 3, an apparatus that is adapted for use in a wireless communications system. An example of a wireless communications system configured in accordance with certain described methods may include a first telecommunications device and a second telecommunications device that may each be capable of communication, such as cellular communication, in a licensed band with a network (e.g. a core network). The network may be configured in accordance with a standard such as LTE, or alternatively may employ other mobile access mechanisms such as wideband code division multiple access (W-CDMA), CDMA2000, High-Speed Packet Access (HSPA), global system for mobile communications (GSM), general packet radio service (GPRS), LTE-Advanced (LTE A), wireless local area network (WLAN), Worldwide Interoperability for Microwave Access (WiMAX) and/or the like.

The transmitter 310 shown in FIG. 4A comprises a source 410, and encoder 420 and a modulator 430. Source 410 is a component and/or process that generates data to be transmitted over the communication channel 320 to the receiver 340. Source 410 passes data for transmission to the encoder 420. This data may comprise a number of data vectors d=(d₁, d₂ . . . dₖ). In this case the encoder encodes a data vector d according to a low-density parity-check coding scheme. For each data vector, the encoder outputs a code vector c=(c₁, c₂ . . . cₙ), where n>k. As an example, n may be 12000 bits and k may be 6000. The encoder 420 generates (n−k) parity bits. In the previous example, for a 1/2 code rate there will be 6000 data bits and 6000 parity bits. For a 4/5 code rate and a code vector of 6000 bits in length there will be 4800 data bits and 1200 parity bits. The code vectors output by the encoder 420 are sometimes referred to as a data block, with an output code defined as an (n, k) block code. In FIG. 4A, the data block output by the encoder 420 is passed to a modulator 430 for modulating the received data block for wireless transmission via one or more antennas 440. FIG. 4A is a simplification to better explain the context of the described examples; in an LTE transmitter for example there may be further channel coding and orthogonal frequency division multiplexing, as well as multiple antennas. In a wired example, the encoded data is prepared accordingly for a channel medium.

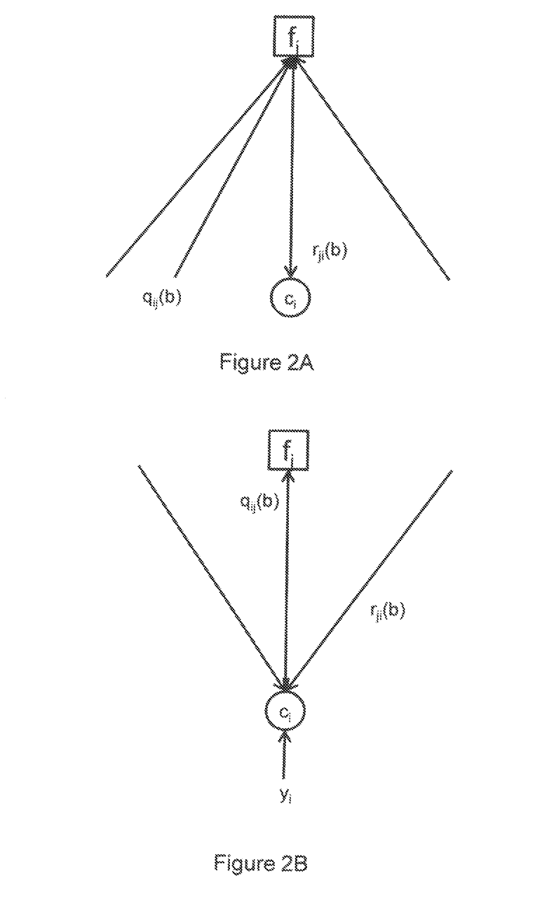

FIG. 4B shows an example of the receiver 340 of FIG. 3, an apparatus that is adapted for use in a wireless communications system. A modulated signal is received at one or more antennas 450 and passed to a demodulator 460 for demodulation. During demodulation, a received code vector c′ is extracted from the signal transmitted over the communication channel 320. The received code vector c′ may contain one or more errors that have been introduced by transmission factors. For example, in a simple case the received code vector c′ may be modelled as the transmitted code vector c plus an error or noise vector e, e.g. c′=c+e. In a low-density parity-check coding scheme the decoder 470 may implement the iterative decoding algorithm demonstrated in FIGS. 2A and 2B to correct any errors and output a received data vector d′ to output 480. For example, a parity check may be applied within an algorithm. This parity check may compare a parity bit or vector p that is calculated using the received code vector c′ with a received parity check bit or vector p′, e.g. as described for check nodes 120. If forward error correction is successful d′ may equal d, i.e. the received data vector is equal to the transmitted data vector. The received data vector is then ready for use in a receiving apparatus.

In an exemplary wireless communication system, parameters for an encoder and a decoder will define a particular code that has been used to encode transmitted data. An encoder and a decoder may perform different operations on data. A decoder that has knowledge of the code that is transmitted may successfully decode encoded data. In certain cases, successful decoding may not always be possible even if a code is known, for example a signal to noise ratio may be low indicating that a transmitted code is overwhelmed by noise. In certain communication techniques a receiver has knowledge of a set of possible codes and a transmitter is allowed to apply any code in that set at transmission time. A decoder of the receiver may then use the set of allowed codes to detect which code was used.

A transmitter and/or a receiver in a communication system may comprise one or more processors and one or more memories. These components may process computer program code to implement one or more of transmitter and receiver functionality as described in the examples herein. A transmitter and/or a receiver in a communication system may also comprise additional functional components that interact with said one or more processors and said one or more memories to implement one or more of transmitter and receiver functionality as described in the examples set out herein.

In a telecommunications system, a user equipment (UE) communicates with a base station, such as an eNB (eNodeB). The UE and/or the base station may comprise one or more of a transmitter and receiver as described herein. For example, a UE may receive, at a receiver of the UE, encoded data transmitted from a transmitter of an eNB and/or may transmit, via a transmitter of the UE, encoded data to a receiver of the eNB. Similarly, an eNB may receive, at a receiver of the eNB, encoded data transmitted from a transmitter of a UE and/or may transmit, via a transmitter of the eNB, encoded data to a receiver of the UE. Alternatively, in certain cases, communication may be end-to-end between a first UE and a second UE, e.g. a first UE may receive, at a receiver of the first UE, encoded data transmitted from a transmitter of a second UE and/or may transmit, via a transmitter of the first UE, encoded data to a receiver of the second UE. These transmissions may be direct or indirect, e.g. data may be communicated between two or more UE through one or more intermediate devices such as network infrastructure. In this case, encoding may be performed on one UE and decoding on another UE.

A UE may have one or more of an encoder and decoder. In some cases, the UE encodes one set of data using the encoder and decodes a different set of data using the decoder. The encoding and decoding operations may use the same or different error correction schemes; e.g. an eNB may use a particular type of encoding for transmitting data to a UE but a UE may use a different type of encoding to transmit data back to the eNB or to another UE. Certain receivers such as video and/or audio devices receiving electromagnetic waves may only contain a receiver.

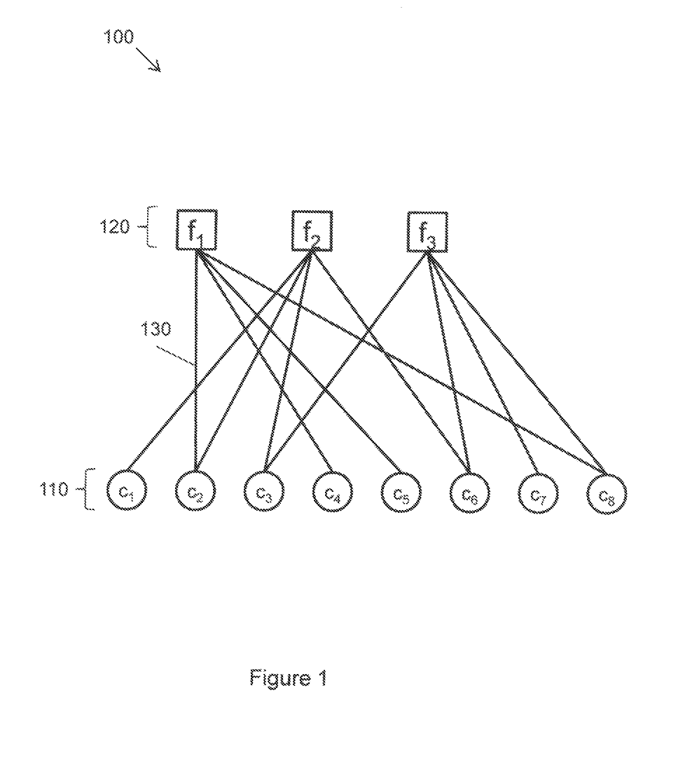

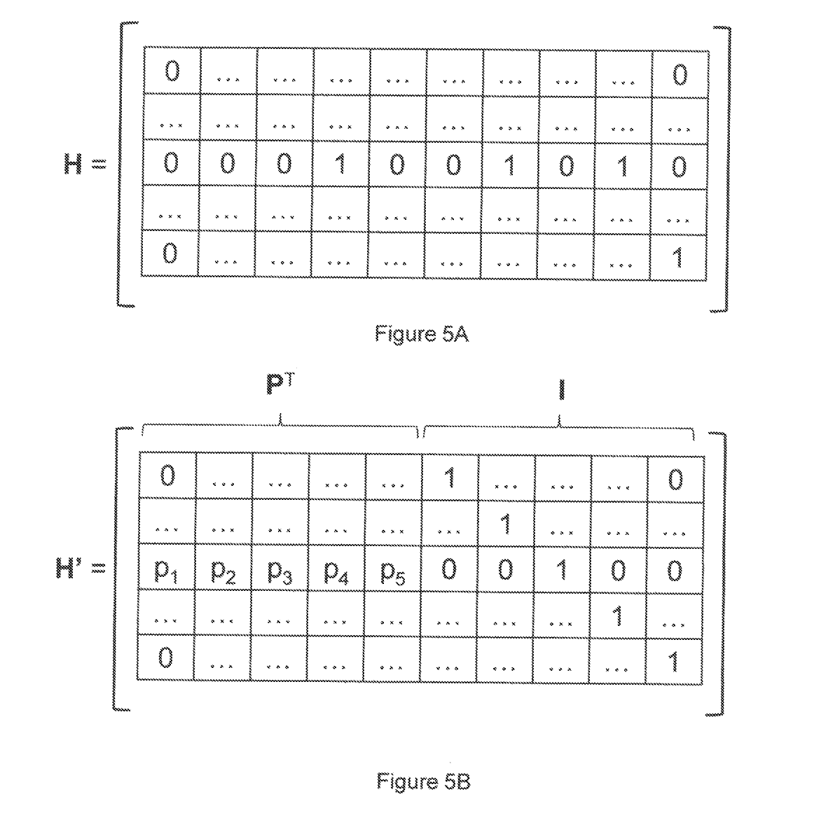

FIG. 5A shows an example of a low-density parity-check matrix H. As described previously with reference to FIGS. 1, 2A and 2B, the columns of the low-density parity-check matrix H represent the connections of each variable node 110 used to implement a low-density parity-check decoder and the rows represent the connections of each check node 120 used to implement the low-density parity-check decoder. As such, if the matrix H is of size m×n then each code vector c of the low-density parity-check code has a length n and satisfies the following linear equation:

c·H^{T}=0.

A low-density parity-check matrix such as H may be placed in a systematic form H′=[P^{T}|I] via Gaussian elimination, where P^{T} is a transposed version of a sub parity matrix P of a size k×m, where k=n−m, I is a m×m identity matrix, and where k is the length of the input data vector d. This form is shown in FIG. 5B. Nevertheless, the original matrix H and its systematic counterpart H′ determine the same code, in other words, c·H^{T}=c≐H′^{T}=0 for all code vectors c of H.

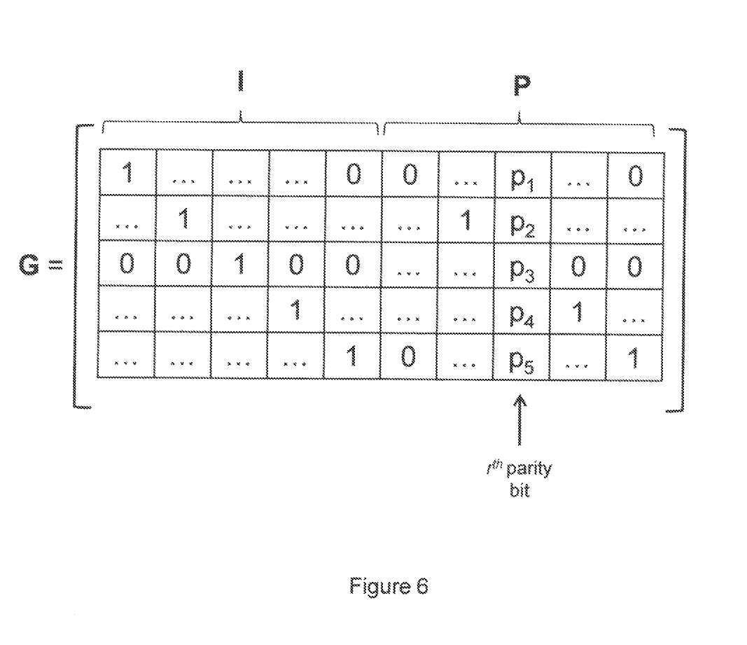

From the form shown in FIG. 5B, a generator matrix may be derived as G=[I|P], where P is a sub matrix of dimensions k×m where k=n−m and I is a k×k identity matrix. The number of parity bits in the parity vector p, a sub vector of the code vector c, is equal to the length of the code vector c minus the length of the data vector d. In general, a size of a sub identity matrix of H′ may differ from that of G. An example of a generator matrix G is shown in FIG. 6. Rows of the generator matrix G are code vectors. Therefore G·H^{T}=G·H′^{T}=0 as well.

Although the matrix H is sparse its systematic counterpart via Gaussian elimination H′ may not be sparse. Encoding of data vectors in terms of H is tedious and therefore H′ is applied for encoding. A large size of H results in a complex application of Gaussian elimination. This makes it difficult to provide H′ or G and thus commercial communication systems.

In a comparative example, a generator matrix G is used to calculate a code vector c according to the equation: c=dG. For systematic codes, a resultant code vector c feature the data vector d in an unmodified form. A low-density parity-check codes, where a generator matrix can be written in the form G=[I|P], is a systematic code, as this equation can be decomposed into a portion that passes through the data vector d, i.e. d·I, and a portion that calculates the parity bits in the parity vector p, i.e. p=d·P. Each column in the parity matrix P can be represented as a vector of parity-check terms [p₁, p₂, p₃, . . . , pₖ] as shown in FIG. 6. In a binary system, these parity-check terms p, have a value of 1 or 0. For an r^{th} column, if the value is 1 then a corresponding i^{th} data vector bit d, is to be used to calculate an r^{th} parity bit p[r], because d·P, per column, results in [d₁·p₁+d₂·p₂+d₃·p₃++dₖ·pₖ] and a value of 0 would produce an output of 0. In this case, an r^{th} parity bit p[r]=d₁·p₁[r]+d₂·p₂[r]+d₃·p₃[r]++dₖ·pₖ[r], typically as a modulo 2 function, where dᵢ ε{0,1} and pᵢ[r] ε{0,1}.

In a low-density parity-check code, the number of parity check terms is constrained by a row weight wᵣ in the low-density parity-check matrix H, where the row weight is the number of 1s in a row. For example, for a sparse matrix of size m×n to be used for determining low-density parity-check codes: wᵣ<<m. Hence, even for code vector lengths of 7000 bits (i.e. n=7000), there may be only 10⁰ or 10¹ parity check terms with a value of 1. For a 1/2 code rate with a data vector d of length 6000 bits, i.e. k=6000, the equation p[r]=d₁·p₁[r]+d₂·p₂[r]+d₃·p₃[r]++dₖ·pₖ[r] would have 6000 multiplications and (k−1) additions. However, if it is known that only a few, e.g. of the order of 10⁰ or 10¹, of these terms will be non-zero then this equation may be seen as the selection and addition of a subset of bit values in the data vector d. By concentrating on positive bit values (i.e. ‘1’s), certain examples described herein offer a simple and easy-to-implement parameterisation of a low-density parity-check matrix, for example as may be used in an encoder. If the term dᵢ·pᵢ[r] has a positive parity-check term, i.e. pᵢ[r]=1, then this is equivalent to selecting the i^{th} bit value of the data vector d, i.e. d, pᵢ[r]=Similarly, if the term dᵢ·pᵢ[r] has a zero-value parity-check term, i.e. pᵢ[r]=0, then this term may be ignored, i.e. dᵢ·pᵢ[r]=0. As the parity check equation for a row now involves the selection of particular bit values in the data vector d, this selection may be achieved by one or more interleavers. The mapping performed by each interleaver can be configured to generate a random or pseudo-random bit selection that conforms to the constraints of the low-density parity-check matrix H. The low-density parity-check matrix can be in a systematic form, that is, H′=[P^{T}|I], or in a non-systematic form (H).

Certain methods and apparatus are described herein that implement a low-density parity-check coding scheme. In these methods and apparatus, one or more interleavers are used to determine the positions of positive bit values (i.e. 1s) in a low-density parity-check matrix, in particular the positions of positive bit values that are used to calculate a parity check bit according to a parity check function. This enables a low-density parity-check matrix to be implemented or ‘parameterised’ in a simple manner. These methods and apparatus enable a simple, low-cost implementation. It is possible to use one or several interleavers at a time.

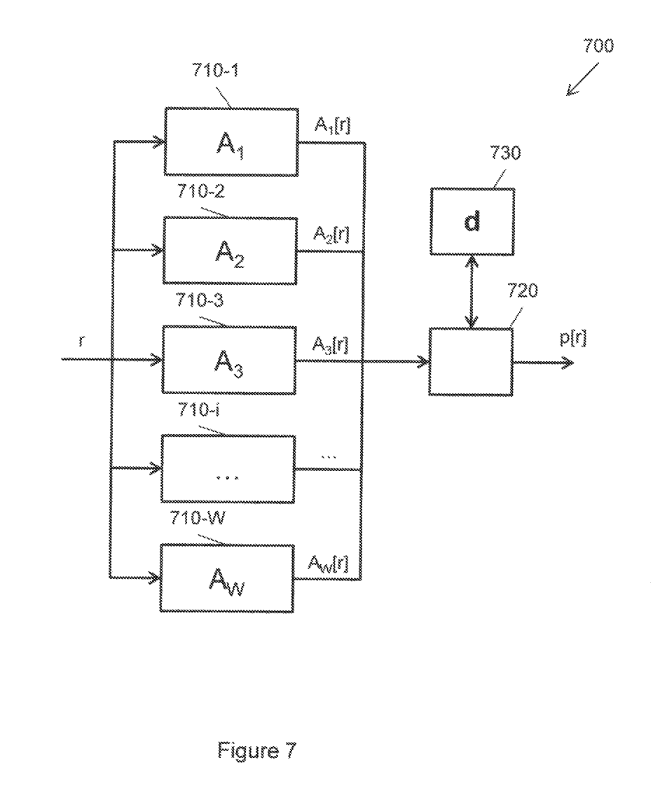

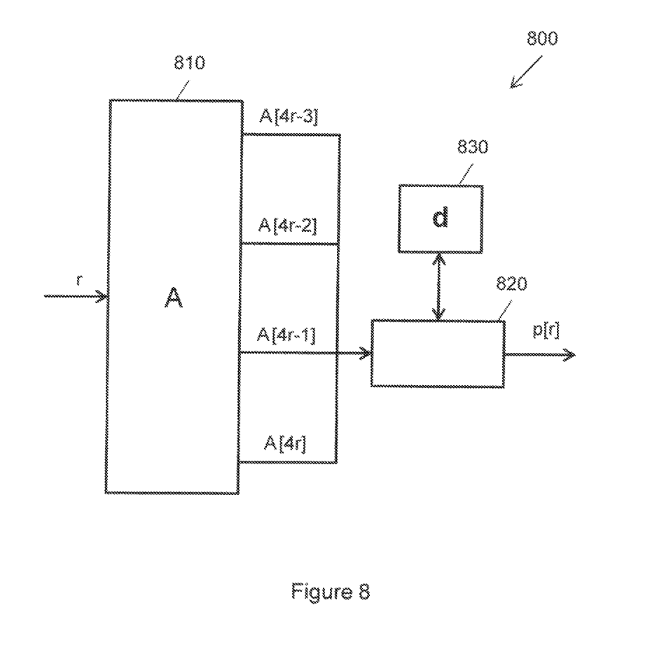

FIG. 7 shows a first example of apparatus 700 that implements a low-density parity-check coding scheme using one or more interleavers 710. In FIG. 7, ‘W’ interleavers are used. In the present example, the interleavers 710 are electronically coupled to a coding component 720. In one example, the coding component 720 is an encoder. The coding component 720 is then electronically coupled to a memory 730. In other examples different couplings are possible.

Each interleaver receives a first address or index r. In this example the first address r corresponds to a row of a low-density parity-check matrix, H, in a systematic form for the apparatus. Equivalently, the address r may also be said to correspond to a column index of a sub matrix P of a generator matrix G, G=[I|P].

Each interleaver maps the first address r to a second address Aᵢ[r]. The range of the second addresses is from 1 to k=m−n. The second address Aᵢ[r] is then output by each interleaver 710 and passed to the coding component 720. The coding component 720 receives the set of W second addresses Aᵢ[r] and uses these to retrieve particular bits of a data vector d. In the example of FIG. 7 the coding component 720 retrieves the bits of the data vector d from a memory 730, wherein the second addresses A[r] are used to address the required bits of the data vector d in the memory 730. In other implementations, the coding component 720 may receive and store the data vector d and perform a local bit look-up operation using the second addresses. In any case, the coding component 720 calculates a parity check bit p[r] corresponding to the row of the low-density parity-check matrix or the column of the generator matrix using the bits of the data vector addressed or indexed by the second addresses Aᵢ[r]. The parity check bit p[r] may be calculated according to the following equation:

p[r]=(d[A₁[r]]+d[A₂[r]]+d[A₃[r]]+ . . . +d[Aᵢ[r]]+ . . . +d[A_{W}[r]])modulo 2

where r=1, 2 . . . N. If the low-density parity-check matrix, H, is of size m×n then N=m, i.e. the number of rows in the matrix. In other examples, other equivalent parity check functions may alternatively be used. The parity check bits p[r] may then be combined in a parity check vector p, which may be appended to the data vector d to produce a code vector c=(d|p). The code vector c may then be transmitted as described in relations to FIGS. 3, 4A and 4B. This kind of a representation for a matrix H produces a systematic low-density parity-matrix which can be guaranteed to be a sparse matrix.

In a variation of the example of FIG. 7, a receiver, for example, as in FIG. 4B, that processes a noisy code vector c′ may use interleavers in a similar manner. For example, a decoder may use one or more interleavers to determine valid candidate codes used in a communication session in order to able to decode a received code vector. In certain cases, a decoder may additionally take advantage of the same interleavers as the encoder did for encoding. In these cases a coding component comprises a decoder and in place of the data vector d, the noisy code vector c′ is retrieved. For example, for decoding, soft bits of a received noisy code vector c′ corresponding to a functional node r have second addresses A₁[r]. A₂[r], A_{W}[r]. An address (n−m+r) corresponds to a soft parity check bit of an r^{th} parity check equation. As in the encoder above, r=1, 2, . . . , m.

In variations of the example of FIG. 7, one or more interleavers 710 may be provided as part of a single chip or circuit arranged to output a vector of second addresses A[r]=(A₁[r], A₂[r] . . . A_{W}[r]) or a matrix of second addresses:

$$A = [ \begin{matrix}{A}_{1} [ 1 ] & {A}_{2} [ 1 ] & … & {A}_{W} [ 1 ] \\ {A}_{1} [ 2 ] & {A}_{2} [ 2 ] & … & … \\ … & … & … & … \\ {A}_{1} [ ( N ) ] & {A}_{2} [ ( N ) ] & … & {A}_{W} [ ( N ) ]\end{matrix} ]$$

In certain variations, interleavers 710 do not receive a first address k. For example, a counter or timer may be used to iterate through the values of k from 1 to N or the interleavers may be configured to output a matrix as shown above of size N×W. Alternatively, the interleavers may have access to memory 730 or be supplied with data vector d and as such retrieve the appropriately addressed bits of the data vector d for passing to the coding component 720.

In an example with a data vector d of length 6000 bits and a required code rate of 1/2, five interleavers may be arranged to generate 6000 parity bits, i.e. W=5 and N=6000. A total size of H is 6000×12000 bits in a systematic form.

In one variation, the example apparatus of FIG. 7 may be adapted for use in both an encoding and decoding process, with the data vector d or the received code vector c′ be alternatively loaded into memory 730 by a controller.

FIG. 8 shows a second example of apparatus 800 that implements a low-density parity-check coding scheme using at least a first interleaver 810. In this example, the first interleaver 810 is electronically coupled to a coding component 820. The coding component 820 is then electronically coupled to a memory 830.

In FIG. 8, the first interleaver 810 receives a row index r corresponding to a row of a low-density parity-check matrix, H, in a systematic form for the system. As earlier, the address r corresponds a row index of H or a column index of a sub matrix P of a generator matrix G, G=[I|P] (the two are equivalent). The first interleaver 810 determines a plurality (i.e. of number ‘W’) of first addresses fᵢ(r) corresponding to the particular row in the low-density parity-check matrix, or the column of the generator matrix, i.e. f₁(r)=4r−3, f₂(r)=4r−2, f₃(r)=4r−1 and f₄(r)=4r where W=4. The first interleaver 810 then maps each of the first addresses to a particular second address A[fᵢ(r)]. The set of second addresses (four in FIG. 8) are then passed to the coding component 820. As in the example of FIG. 7, coding component 820 receives the set of second addresses A[fᵢ(r)] and uses these to retrieve particular bits of a data vector d. As with the example of FIG. 7, the coding component 820 retrieves the bits of the data vector d from memory 830, wherein the second addresses A[fᵢ(r)] are used to address the required bits of the data vector d in the memory 830. Again, in other implementations the coding component 820 may receive and stores the data vector d and perform a local bit look-up operation using the second addresses. In any case, the coding component 820 calculates a parity check bit p[r] corresponding to the row of the low-density parity-check matrix using the bits of the data vector addressed or indexed by the second addresses A[t(r)]. Hence, the parity check bit p[r] may be calculated according to the following general equation:

p[r]=(d[A[f₁(r)]]+ . . . +d[A[f₁(r)]]+ . . . +d[A[f_{W}(r)]])modulo 2

or in the present example:

p[r]=(d[A[4r−3]]+d[A[4r−2]]+d[A[4r−1]]+d[A[4r]])modulo 2

where r=1, 2 . . . N/4 and N=6000. In an example with a data vector d of length k=6000 bits, there will be m=1500 rows and n=7500 columns in the low-density parity-check matrix and a code rate of 4/5. In other examples, other equivalent parity check functions may alternatively be used. The parity check bits p[r] may then be combined in a parity check vector p, which may be appended to the data vector d to produce a code vector c=(d|p). The code vector c may then be transmitted as described in relations to FIGS. 3, 4A and 4B.

In a variation of the example of FIG. 8, one or more further interleavers may be added to generate a lower code rate if desired. In order to create a low-density parity-check code having a code rate 12/19 from the above code of the code rate 4/5 we may apply a second interleaver A′ of length 6000 to encode a second parity check vector of 2000 bits by:

p[r+1500]=(d[A′[3r−2]]+d[a′[3r'1]]+d[A′[23r]])modulo 2

where r=1, 2, . . . , 6000/3 (i.e. to 2000). As a result, the rows of the low-density parity-check matrix H in a systematic form from 1 to 1500 are determined by the matrix A and the rows from 1501 to 3500 are determined by the matrix A′. A third interleaver may be used to lower a code rate further if desired. The kind of code is useful for communication systems which apply an incremental redundancy or a (hybrid) automatic repeat request for re-transmissions of data.

As with the apparatus of FIG. 7, the parameterisation, explained with reference to the example of FIG. 8, may also be adapted for decoding a received noisy code vector c′. In this case a receiver, for example, as in FIG. 4B, processes a noisy code vector c′, e.g. instead of a data vector d, and takes advantage of interleavers in a corresponding manner to an encoder. Soft bits of the noisy code vector corresponding to a functional node r have second addresses A[fᵢ(r)], and the address (n−m+r) corresponds to a soft parity check bit of an r^{th} parity check equation. As in the encoder above, r=1, 2, . . . , m.

The manner in which the interleavers described above parameterise a low-density parity-check code will now be described in more detail for low-density parity-check matrixes which can be in a non-systematic form. One or more interleavers are defined over a length of a code vector c and they determine which bits (or soft bits at a decoder) of a code vector take part in which parity checks. Each interleaver receives a first address or index r. This first address r corresponds to a row of an m×n low-density parity-check matrix, H, in a non-systematic form for the system. The first address r takes values from 1 to m. Each interleaver maps the first address r to a second address Aᵢ[r]. The range of the second address is from 1 to n. Then second addresses A₁[r], A₂[r], A_{W}[r] specify positions of ones in the row r of the low-density parity-check matrix H. FIG. 5A shows an example of a low-density parity-check matrix H which has three ones in the row r=3 at positions 4, 7, and 9. In the case of FIG. 5A, three interleavers can output respective values of A₁[3]=9, A₂[3]=4, and A₃[3]=7. It may happen that two or more interleavers are equal at some row r_{eq}, for example, A₁[r_{eq}]=A_{W}[rₑₑ]. This means that the row r_{eq} has W−1 bits having a value of ‘1’ instead of W bits having a value of ‘1’. A corresponding low-density parity-check code is then irregular because a number of ones (i.e. bit values of ‘1’) in a plurality of rows is not constant, i.e. each row may have a different number of ones.

Even though a low-density parity-matrix in a non-systematic form may not be useful for encoding data vectors in certain comparative examples, in certain examples described herein a decoder can take advantage of a low-density parity check matrix in a non-systematic form in order to process variables nodes 120 and check nodes 110 as shown in FIGS. 1, 2A and 2B.

In one example, such as one using the system of FIG. 7, the number of interleavers is selected dependent on the column weight of the low-density parity-check matrix H′. A typical interleaver performs a one-to-one mapping of a first range of indices 1 to N to a second range of indices 1 to N. Hence, when interleavers are selected to have a length equal to the number of rows of the low-density parity-check matrix H′, i.e. have an input range of r=1 to N and an output range of A[1] to A[N], then each bit value in the data vector d can only be used once in the set of parity check equations p[1] to p[N]. This would correspond to there being only one non-zero value (i.e. bit value=1) in each column of the low-density parity-check matrix when in the form H′. As the examples described herein can be equally applied to parameterise low-density parity-check matrices in either form H or H′, a similar selection may be applied to H. In general, each interleaver contributes to a row weight (in terms of a low-density parity-check matrix H) or a column weight (in terms of a generator matrix G). Therefore, by manipulating a number of interleavers and/or properties of individual interleavers one can construct matrixes of good codes. These codes can be regular or irregular, systematic or non-systematic, as well as other characteristics. An irregular code can be configured to approach a Shannon capacity limit to a specified degree. An appropriate search or optimisation algorithm can be used to determine these variables.

In a similar manner, apparatus such as that illustrated in FIG. 8, provides a similar effect by mapping a particular row in the low-density parity-check matrix H to a plurality of bit selections in the data vector d.

When using more than one interleaver, there can be used a constraint that at least two mappings of a common first address r must produce different, i.e. distinct, second addresses for each interleaver. This represents the constraint that at least two bit values in the data vector d shall be used in a parity check equation for a row p[r]. An even number of interleavers having a same address at some r removes that particular bit from a parity check equation for that r. Hence, mappings for at least two interleavers may be generated such that Aᵢ(r)≠(r) when i≠j. In certain cases this may be achieved using orthogonal mappings. Likewise, this applies when using more than one interleavers in the system illustrated in FIG. 8. It also applies to the set of second addresses produced for the parity check equation used with the system of FIG. 8; these may be distinct. This will be the case if a first interleaver is used that implements a one-to-one mapping between the set of first addresses and the set of second addresses. Having a constraint that interleavers shall have different address per parity check equation prevents a parity check equation from degenerating, i.e. being empty.

In one example, the lengths of a set of interleavers are equal. For example, all the interleavers of FIG. 5 may have equal lengths (i.e. all output values in a range 1 to N). These lengths may equal the number of columns in the low-density parity-check matrix H. In other examples, a length of one or more interleavers may be shorter than one or more other interleavers in a set. This may represent an internal structure for positions of ones in a low density parity check matrix. For example, if P^{T} has one or more triangular sub-matrices an interleaver need not output the full range of bit addresses in the data vector d. For example, if due to triangular nature of a sub-matrix all parity check terms relating to data vector bits beyond a particular address value were 0, then the output range of the interleaver need not include addresses above said particular address value. A short interleaver may be implemented with an offset address in order to ensure it has an address space that intersects an address space of at least one other short interleaver, while having other distinct address space portions.

For instance, let a length of a data vector d be 1000 bits. In this example, a first interleaver A₁ may be defined to map first addresses comprising integers in the range of 1 to 1000. A second interleaver A₂ may then be defined to map first addresses comprising integers in the range of 1 to 500, and a third interleaver A₃ may be defined to map first addresses comprising integers in the range of 1 to 700. In this case, the three interleavers are applied to generate second addresses to retrieve data using the formulae: A₁[r], 50+A₂[(r modulo 500)+1], and 250+A₃[(r modulo 700)+1], where r=1, 2, . . . , 800 for parity-check bit operations. The two modulo terms, (r modulo 500) and (r modulo 700), ensure that inputs to A₂ and A₃ are in a valid range. The offsets 50 and 250 regulate how address ranges of A₂ and A₃ intersect. In this particular case, the interleavers A₂ and A₃ generate overlapping addresses. This means that corresponding data bits take part in multiple parity checks in an encoder or help define multiple functional nodes in a decoder. On the other hand, the interleaver A₁ is not used over an entire address space, instead it is used in a first address sub-space that ranges from 1 to 800. The code rate of this code is 1000/1800=5/9 and the code is specified in a systematic form. Nevertheless, this kind of use of interleavers can also be applied to code matrices in a non-systematic form. In this case a basic range of one or more interleavers is a row dimension of a code matrix.

In one variation, one or more permutation polynomial interleavers may be used. These enable an interleaver to be defined with only a few parameters, each parameter representing a different power term. For example, a quadratic permutation polynomial may be defined by two parameters, and as such a low-complexity interleaver implementation is achieved (e.g. for 5 interleavers only 10 parameters need be configured—as compared with a matrix of 36 million values). This makes quadratic permutation polynomial useful for a low cost and low complexity implementation. Suitable parameter values of one or more permutation polynomial interleavers may be selected to conform to the constraints described above. In one case, a low-density parity-check matrix H may be designed based on the properties of one or more permutation polynomial interleavers. A resulting low-density parity-check code may then be validated by simulation. For example, an iterative design method may be used to maximise one or more communication metrics subject to the described constraints. These one or more metrics may comprise, for example, one or more of a distance property of candidate codes, a randomness metric measuring the location of positive bit values in the low-density parity-check matrix, a sparseness measure for the low-density parity-check matrix etc. For example, it has been shown that a random position of positive bit values in the low-density parity-check matrix results in better low-density parity-check codes. This may be achieved by selecting interleaver mappings that have good randomness properties.

For a given low-density parity-check matrix H, once an interleaver-based parameterisation has been implemented in an encoder, a decoder may be constructed and/or configured based on the given low-density parity-check matrix H. In certain examples one or more of the encoding and decoding processes make use of the parameterisation of a coding matrix as described herein. In decoder examples, the interleavers may be used to provide addressing for message passing when implementing the decoder. A decoder may use a different construction and/or different set of inputs from an encoder for implementing a functional node using interleavers.

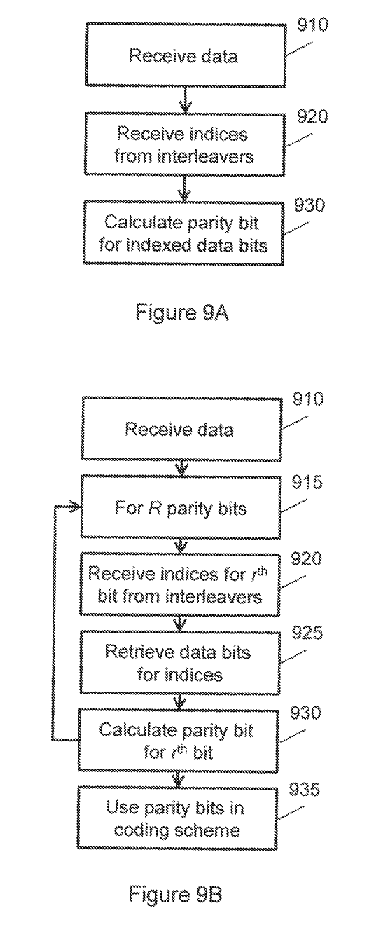

FIG. 9A shows a method of implementing a low-density parity-check code. This method may be used with one of the apparatus of FIG. 7 or 8, or other apparatus. At block 910 data is received. This may be a data vector d that is received from a source such as 410 or a code vector c′ received from a demodulator 460. The data may be stored in a memory and/or passed to one or more coding components. At block 920, a plurality of indices is received from one or more interleavers. These indices may comprise the second addresses described in relation to FIGS. 7 and 8. The indices may be received in accordance with a row identifier for a particular vector of a coding matrix, e.g. a row of a given low-density parity-check matrix. At block 930, the indices are used to identify a plurality of data bits in the data. These data bits are then used in a parity check function to calculate a parity bit. For example, a modulo-2 bit summation as described in relation to FIGS. 7 and 8. Blocks 920 and 930 may be repeated for each row of the low-density parity-check matrix.

The method of FIG. 9A may be used to encode data to be transmitted. For example, if the blocks are repeated, the calculated parity bits may be concatenated with data to be transmitted to generate an encoded block. This encoded block may be supplied for further encoding (such as channel coding) and/or modulation. Alternatively, the data may comprise data received over a communication channel. In this case the method of FIG. 9A may be used to retrieve a particular set of received bits in said data. In reference to FIG. 2A, this particular set of received bits may comprise the messages qᵢⱼ(b) that are passed from the variable nodes cᵢ 110 to the check nodes fⱼ 120. The parity bit calculated at block 930 may thus represent a parity check applied by a check node 120, and as such may be used to return a hard or soft decision bit as result rⱼᵢ(b) to a set of connected variable nodes 110. In this manner the method of FIG. 9A, and be extension the apparatus of FIG. 7 or 8, may be appropriately used for both encoding and decoding data in an implementation of a low-density parity-check scheme.

FIG. 9B shows one method of implementing a low-density parity-check code. This method may also be used with one of the apparatus of FIG. 7 or 8, or other apparatus. Certain blocks of the method of FIG. 9B share features with the method of FIG. 9A.

At block 910 data is received. Again, this may be a data vector d that is received from a source such as 410 or a code vector c′ received from a demodulator 460. The data may be stored in a memory and/or passed to one or more coding components. At block 915, a loop is initiated for a plurality of vectors in a coding matrix, which may comprise each row of a low-density parity-check matrix associated with a low-density parity-check code to implement or each column of a parity-check matrix associated with a generator matrix of said code. Or as alternatively described, a loop is initiated for each parity bit to be calculated in a given code vector c of length n. At block 920, indices for an r^{th} bit are determined using one or more interleavers. These indices may comprise the second addresses described in relation to FIGS. 7 and 8. The indices may be determined based on a variable representing r, i.e. in accordance with a vector identifier for a particular vector of a given coding matrix, such as a row of H. At block 925, the indices are used to determine a particular subset of data bits in the data received at block 910. At block 930, the particular subset of data bits are used in a parity check function to calculate an r^{th} parity bit; for example, using a modulo-2 bit summation as described in relation to FIGS. 7 and 8. After this calculation blocks 920, 925 and 930 are repeated as part of the loop initiated at block 915 if there are more parity bits to calculate, e.g. if r does not equal R. At block 935, after the method has been repeated for all associated vectors of the coding matrix, for example all rows or columns of a low-density parity-check matrix or generator matrix, the calculated parity bits are used to implement the low-density parity-check coding scheme. For example, they may be concatenated with the data received at block 910 to generate an encoded block. Again, this encoded block may be supplied for further encoding (such as channel coding) and/or modulation. Alternatively, the parity bits may be used in a decoding process, e.g. to calculate soft bits for use in an iterative decoding process as illustrated in FIGS. 2A and 2B.

Certain described examples, simplify the process of defining where ones in a low density parity check matrix are positioned making low-density parity-check codes flexible and useful channel codes for commercial wireless communication systems. For example, the apparatus and methods described herein may be applied in a device for wireless communication. They enable flexible set of codes to be generated with variable code rates and code word lengths. These examples may be distinguished from implementations where interleaving is performed upon a code vector c produced based on a low-density parity-check code. In these latter implementations, the code vector c (that is later interleaved) is generated by the matrix multiplication d·G, with the generator matrix G being stored in memory. Interleavers are not used to define or implement a given low-density parity-check matrix H. Certain present examples avoid the need to store a large generator matrix in memory.

Although examples herein are described in terms of a binary field (a bit) that is used to present data symbols (or digits), the described examples of interleaver-based parameterisation can be applied to matrices of non-binary symbols. In this case, a corresponding finite field to which symbols belong determines one or more arithmetic rules for parity checks. As described, a low-density parity-check matrix H has a systematic form H′=[−P^{T}|I]. When a binary field is used the minus sign in front of the sub matrix P^{T} degenerates away, i.e. P=−P. A generator matrix G with symbols in a non-binary field is formally the same as in a binary case: G=[I|P]. Hence, one or more interleavers may be applied to specify non-zero elements of H, H′ or G on that particular (non-binary) field.

The methods and apparatus described herein may form part of a specification for parameters for channel codes. This specification may indicate that parameters are to be selected and/or applied as set out in one or more of the examples herein. The specification may also indicate how one or more of said parameters are to be communicated in a telecommunications system; for example, in simplex or duplex communication between a transmitter and a receiver (e.g. between a user equipment and a base station or between two user equipments).

The nature of particular parameters and their communication to telecommunications equipment may depend on a type of air interface used by a technical standard, e.g. how a UE communicates with a base station. In standards set by European Telecommunications Standards Institute (ETSI), for example GSM, 3G, HSPA, and LTE, a three layer structure is used to specify air interfaces. In these cases, the methods and systems described herein may be used as part of channel coding methods applied in the lowest layer, layer 1. In certain cases where channel coding belongs to a lowest level in an air interface structure, explicit parameters for channel codes may be derived from other parameters, for example those communicated as part of other layers. In these cases, the explicit channel coding parameters may not be used to set up a communication. As such, parameters used for encoding and/or decoding as described herein may not be explicitly communicated and may be derived from other information communicated to and/or local to a telecommunications device.

As further example, in a telecommunications system, a packet data channel may be associated with one or more control channels. A receiver may be arranged to continuously monitor these control channels to detect if a transmitter is sending a packet data frame to that particular receiver. The receiver may have a key to open control channels specifically intended for the device. Successfully opened control channels may carry configuration information such as, amongst others: a type of channel coding; a number of data bits for transmission in each encoded block; an interleaver configuration including which interleavers are in to be used and how; a modulation configuration; and a HARQ-process configuration. This configuration information may then be used to carry information for configuring a receiver and/or transmitter according to the methods and apparatus described herein. In certain cases, a receiver may communicate information associated with a radio access configuration. For example, a receiver may specify, in an uplink channel to a transmitter, a preferred set of one or more air interface parameters than can be used in a particular environment. These parameters may ensure that the receiver can maintain successful communication, e.g. that errors can be corrected by the receiver. As such one or more low-density parity-check codes may be configured for use, as described herein, in specific circumstances, e.g. low signal-to-noise ratio, high signal-to-noise ratio etc. In each circumstance a code may have different properties, e.g. lower or high code rates, be longer or shorter, etc.

The methods and apparatus described herein may also be used in coding schemes other than those used for wired or wireless communication. For example, they may be implemented as part of a coding scheme for data storage. They may thus be applied to computing device and/or storage devices such as magnetic and solid state disk drives, media drives, memory devices etc.

It will be understood that the apparatus referred to herein may in practice be provided by a single chip or integrated circuit or plural chips or integrated circuits, optionally provided as a chipset, an application-specific integrated circuit (ASIC), field-programmable gate array (FPGA), digital signal processor (DSP), etc. The chip or chips may comprise circuitry (as well as possibly firmware) for embodying at least one or more of a data processor or processors, a digital signal processor or processors, baseband circuitry and radio frequency circuitry, which are configurable so as to operate in accordance with the exemplary embodiments. In this regard, the exemplary embodiments may be implemented at least in part by computer software stored in (non-transitory) memory and executable by the processor, or by hardware, or by a combination of tangibly stored software and hardware (and tangibly stored firmware).

The methods and apparatus described herein may be applied to wired and wireless communication systems. In the latter, the methods and apparatus described herein may be incorporated into one or more wireless devices, which include in general any device capable of connecting wirelessly to a network, and includes in particular mobile devices including mobile or cell phones (including so-called “smart phones”), personal digital assistants, pagers, tablet and laptop computers, content-consumption or generation devices (for music and/or video for example), data cards, USB dongles, etc., as well as fixed or more static devices, such as personal computers, game consoles and other generally static entertainment devices, various other domestic and non-domestic machines and devices, etc. The term “user equipment” or UE is often used to refer to wireless devices in general, and particularly mobile wireless devices.

The terms “transmitter” and “receiver” are also used herein and are to be construed broadly to include the whole of a device that is transmitting/receiving wireless signals as well as only particular components of a device that are concerned with transmitting/receiving wireless signals or causing or leading to the transmission/reception of wireless signals.

As described in examples herein, a method of implementing a low-density parity-check code comprises: receiving data; for a plurality of vectors in a coding matrix associated with the low-density parity-check code: retrieving, from one or more interleavers, one or more addresses; using said one or more retrieved address to retrieve one or more symbols from said data; and performing a parity-check operation corresponding to a particular said vector using said one or more symbols retrieved from said data, wherein each of the performed parity-check operations are used to implement the low-density parity-check code.

In an example, each symbol is a bit. In one case a parity check operation comprises a parity-check bit calculation in an encoder. In another case a parity check operation comprises the implementation of a functional node in a decoder.

In an example, retrieving, from one or more interleavers, one or more addresses comprises: determining a first address corresponding to the particular vector; and retrieving, from a plurality of interleavers, a plurality of second addresses using the first address. The number of interleavers may contribute to a weight of each vector in the coding matrix and for each first address, a distinct second address may be retrieved from each of the plurality of interleavers.

In an example, retrieving, from one or more interleavers, one or more addresses comprises: determining one or more first addresses corresponding to at least one vector; and retrieving, from a first interleaver, a respective first set of one or more second addresses using the one or more of first addresses. This may apply for a first subset of vectors or for all vectors. A range of second addresses may contribute to a weight of a particular vector in the coding matrix, e.g. a vector in said subset. In an irregular case, as vector weights may vary per vector, this may not apply. Retrieving may also comprise retrieving from a second interleaver a respective second set of second addresses. This may occur using the same set of first addresses or using a different set of first addresses. The retrieving from a second interleaver may be for the first subset of vectors, a second subset of vectors that differ and/or overlap with the first subset of vectors or all vectors. Other vector combinations are also possible.

In an example, at least one interleaver comprises a permutation polynomial interleaver, such as a quadratic permutation polynomial interleaver.

The coding matrix may comprise one of: a low-density parity-check matrix H in a non-systematic form, wherein a vector comprises a row of said matrix; a low-density parity-check matrix H′ in a systematic form, wherein a vector comprises a row of said matrix; a generator matrix G, wherein a vector comprises a column of said matrix. Each interleaver may have a length determined by a dimension of the coding matrix.

The data may comprise a data vector to be encoded, in which case the method may comprise generating an encoded block using the data to be encoded and each of a number of determined parity-check bits. The data may alternatively comprises a code vector received over a noisy communication channel, in which case the method may comprise implementing a functional node in a decoding process to determine data that was sent over the communication channel.

In an example apparatus for implementing a low-density parity-check code comprises at least one memory arranged to store data; one or more interleavers, an interleaver being arranged to implement a mapping between a first address and a second address, a first address being associated with a particular vector in a coding matrix associated with the low-density parity-check code and a second address corresponding to a particular symbol of the data as stored in the memory; a coding component arranged to, for a plurality of vectors in the coding matrix, use one or more second addresses from the one or more interleavers to retrieve one or more symbols of the data stored in memory, the coding component being further arranged to perform at least a plurality of parity check operations, a parity check operation corresponding to a vector in the coding matrix and being performed using said retrieved one or more symbols of the data, the plurality of parity check operations being used to implement the low-density parity-check code.

In one example, the plurality of interleavers are arranged to determine a respective plurality of second addresses based on at least one first address, wherein the coding component is arranged to use said plurality of second addresses to retrieve a plurality of symbols from the memory and perform a parity-operation accordingly using said retrieved plurality of symbol. In this case, the plurality of interleavers may be electrically coupled to at least one of the coding component and the memory and the coding component is electrically coupled to at least the memory. As before, for a regular coding matrix, the number of interleavers in said plurality of interleavers may be dependent on a vector weight of the coding matrix and for each first address, the plurality of interleavers may be arranged to output a respective plurality of distinct second addresses. Each interleaver may be arranged to map a first range of first addresses onto a second range of second addresses, the first and second ranges being determined by a dimension of the coding matrix. In other examples the coding matrix may be irregular.

In one case, the one or more interleavers comprise at least a first interleaver, the first interleaver being arranged to receive a plurality of first addresses corresponding to the particular vector in said plurality of vectors of the coding matrix and map said first addresses to a respective plurality of second addresses. Here, the first interleaver may be arranged to map a first range of first addresses onto a second range of second addresses, at least one of the first and second ranges being proportional to a dimension of the coding matrix, e.g. a first or second range may have a number of values that is a multiple of a number of elements in a dimension of the coding matrix. A second interleaver may also be arranged to output a plurality of second addresses. This may be a different set of second addresses from that output by the first interleaver. The first and second interleavers may operate on subsets of first addresses that are different, that overlap and/or that are the same.

In certain examples, at least one interleaver comprises a permutation polynomial interleaver, such as a quadratic permutation polynomial interleaver.

The coding component may comprise an encoder, in which case the data comprises a data vector to be encoded, and/or may comprise a decoder, in which case the data comprises a code vector received over a communication channel. In an encoder a parity-check operation may comprise calculating a parity check symbol or bit. In a decoder a parity check operation may comprise implementing a functional or check node in a message-passing algorithm. The coding component may also be used as part of one or more of an encoding and a decoding process. Each symbol may comprise a binary field, i.e. a bit.

In one example, the apparatus comprises one or more of a user equipment, a base station, a computing device and a communications device. The communication device may comprise one or more of a transmitter comprising the apparatus and a receiver comprising the apparatus. Any communications device may be a wireless communications device which is wirelessly connectable to a wireless network which is controlled by network control apparatus, for example a communications device arranged to communicate in accordance with one or more of the following: long-term evolution (LTE), wideband code division multiple access (W-CDMA), CDMA2000, global system for mobile communications (GSM), general packet radio service (GPRS), LTE-Advanced (LTE A), wireless local area network (WLAN), and Worldwide Interoperability for Microwave Access (WiMAX).

In accordance with an example, there is provided apparatus comprising: at least one processor; and at least one memory including computer program instructions and data; the at least one memory and the computer program instructions being configured to, with the at least one processor, cause the apparatus at least to, for a plurality of vectors in a coding matrix associated with a low-density parity-check code: retrieve, from one or more interleavers, one or more addresses; use said one or more retrieved address to retrieve one or more symbols from said data in memory; and perform a parity-check operation corresponding to a particular said vector using said one or more symbols retrieved from said data, wherein each of the performed parity-check operations are used to implement the low-density parity-check code.

In accordance with an example. there is provided a method of configuring one or more interleavers for use in implementing a low-density parity-check code comprising: selecting a low-density parity-check matrix; selecting, for a regular low-density parity-check matrix, one of: a number of interleavers and a length of one or more interleavers. This may be based on a predetermined column weight for the low-density parity-check matrix. The method then comprises determining one or more interleaver parameters that implement a mapping for each interleaver from a first address corresponding to a row in the low-density parity-check matrix to a second address corresponding to a bit position in data to be encoded, the mapping being selected from a plurality of potential mappings based on one or more error coding criteria.

In accordance with an example, there is provided a method of configuring one or more interleavers for use in implementing a low-density parity-check code comprising: selecting a coding matrix associated with the low-density parity-check code; and determining one or more interleaver parameters that implement a mapping for one or more interleavers from a first address corresponding to a vector in the coding matrix to a second address corresponding to a symbol position in data to be encoded or decoded, the mapping being selected from a plurality of potential mappings based on one or more error coding criteria.

The above examples are to be understood as illustrative. Further examples and variations are envisaged, some of which are described herein. It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the invention, which is defined in the accompanying claims.

I claim:

1. A method of implementing a low-density parity-check code comprising:
receiving data;
for a plurality of vectors in a coding matrix associated with the low-density parity-check code:
retrieving, from one or more interleavers, one or more addresses;
using said one or more retrieved address to retrieve one or more symbols from said data; and
performing a parity-check operation corresponding to a particular said vector using said one or more symbols retrieved from said data,
wherein each of the performed parity-check operations are used to implement the low-density parity-check code.

2. A method according to claim 1, wherein, for a particular vector of the coding matrix, retrieving, from one or more interleavers, one or more addresses comprises:
determining a first address corresponding to the particular vector; and
retrieving, from a plurality of interleavers, a plurality of second addresses using the first address.

3. A method according to claim 2, wherein the number of interleavers contribute to a weight of at least one vector in the coding matrix.

4. A method according to claim wherein, for each first address, a distinct second address is retrieved from each of the plurality of interleavers.

5. A method according to claim 1, wherein, for at least one vector of the coding matrix, retrieving, from one or more interleavers, one or more addresses comprises:
determining a one or more first addresses corresponding to the at least one vector; and
retrieving, from a first interleaver, a respective first set of one or more second addresses using the one or more first addresses.

6. A method according to claim 5, wherein a range for the respective plurality of second addresses contributes to a vector weight of the coding matrix.

7. A method according to claim 5, wherein, for at least one vector of the coding matrix, retrieving, from one or more interleavers, one or more addresses comprises:
retrieving from a second interleaver a respective second set of one or more second addresses.

8. A method according to claim 1, wherein each interleaver has a length that is proportional to a dimension of the coding matrix.

9. A method according to claim 1, wherein at least one interleaver comprises a permutation polynomial interleaver.

10. A method according to claim 9, wherein a permutation polynomial interleaver comprises a quadratic permutation polynomial interleaver.

11. A method according to claim 1, wherein the coding matrix comprises one of: a low-density parity-check matrix H in a non-systematic form, wherein a vector comprises a row of said matrix; a low-density parity-check matrix H′ in a systematic form, wherein a vector comprises a row of said matrix; a generator matrix G, wherein a vector comprises a column of said matrix.

12. A method according to claim 1, wherein the data comprises a data vector to be encoded, performing a parity-check operation comprises determining a parity-check symbol and the method comprises:
generating an encoded block using the data to be encoded and each of said determined parity-check symbols.

13. A method according to claim 1, wherein the data comprises a code vector received over a noisy communication channel and performing a parity-check operation comprises:
implementing a functional node in a decoding process using said one or more symbols retrieved from said data, the decoding process being used to determine data that was sent over the communication channel.

14. A method according to claim 1, wherein a symbol comprises a bit value.

15. An apparatus for implementing a low-density parity-check code comprising:
at least one memory arranged to store data;
one or more interleavers, an interleaver being arranged to implement a mapping between a first address and a second address, a first address being associated with a particular vector in a coding matrix associated with the low-density parity-check code and a second address corresponding to a particular symbol of the data as stored in the memory;
a coding component arranged to, for a plurality of vectors in the coding matrix, use one or more second addresses from the one or more interleavers to retrieve one or more symbols of the data stored in memory,
the coding component being further arranged to perform at least a plurality of parity check operations, a parity check operation corresponding to a vector in the coding matrix and being performed using said retrieved one or more symbols of the data, the plurality of parity check operations being used to implement the low-density parity-check code.

16. The apparatus according to claim 15, comprising:
a plurality of interleavers arranged to determine a respective plurality of second addresses based on at least one first address,
wherein the coding component is arranged to use said plurality of second addresses to retrieve a plurality of symbols from the memory and perform a parity-check operation accordingly using said retrieved plurality of symbols.

17. (canceled)

18. The apparatus according to claim 16, wherein the number of interleavers in said plurality of interleavers is dependent on at least one vector weight of the coding matrix.

19. (canceled)

20. The apparatus according to claim 16, wherein each interleaver is arranged to map a first range of first addresses onto a second range of second addresses, at least one of the first and second ranges being proportional to a dimension of the coding matrix.

21-25. (canceled)

26. The apparatus according to claim 15, wherein the coding component comprises an encoder arranged to calculate a parity-check symbol in a parity check operation and the data comprises a data vector to be encoded.

27-36. (canceled)

37. A method of configuring one or more interleavers for use in implementing a low-density parity-check code comprising:
selecting a coding matrix associated with the low-density parity-check code; and
determining one or more interleaver parameters that implement a mapping for one or more interleavers from a first address corresponding to a vector in the coding matrix to a second address corresponding to a symbol position in data to be encoded or decoded, the mapping being selected from a plurality of potential mappings based on one or more error coding criteria.
